(19) United States
(12) Patent Application Publication
(10) Pub. No.: US 2005/0136337 A1
(43) Pub. Date: Jun. 23, 2005

(54) Method for forming wires of sub-micron-order scale

(75) Inventors: Yung-Hsiang Wu, Fengyuan City (TW); Je-Ping Hu, Hsinchu (TW); Ming-Huan Yang, Shenkang Hsiang (TW); Chun-Jung Chen, Yuanchang Hsiang (TW); Chien-Hung Liu, Panchiao City (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Industrial Technology Research Institute, Chutung Chen (TW)

(21) Appl. No.: 10/833,209

(22) Filed: Apr. 26, 2004

(30) Foreign Application Priority Data
Dec. 17, 2003 (TW) 092135720

(51) Int. Cl. G03F 9/00; G03F 7/00

(52) U.S. Cl. 430/5; 430/323

(57) ABSTRACT

A method for forming wires of nano-meter grade, wherein by printing or dispensing a solution on a substrate, the solute contained in the solution will form two regions with different thicknesses on the substrate when the solvent has dried. After an etching process is comprehensively applied on the substrate, the region with thinner solute will be completely removed, and only the region with the thicker solute remains as the desired wires. With such a process, the line width of the created wires is narrowed to reach the nano-grade.

### BACKGROUND OF THE INVENTION

1. Field of the Invention

The present invention pertains to a method for forming wires of sub-micron-order scale, and more particularly to a method in which the width of created wires can be narrowed based on an effect called “coffee ring” in company with an etching process.

2. Description of Related Art

Most electronic components are fabricated through semiconductor manufacturing processes in which a well known process called photolithography is adopted for circuit patterns transfer from a photo-mask to a target such as a substrate. However, the application of such a high-cost process still has some limitations that are difficult to overcome. Therefore, many techniques intended to replace the conventional photolithography process have been developed in recent years. A feasible way, i.e., a direct writing process, is applied to create these circuit patterns or components by printing appropriate substance on substrates.

The advantages that lead the direct printing process include the following points.
1. Reducing the high cost of the photo-mask usage, and be suitable to be applied to fabricate a small amount of the high-price products.
2. Raising the effective utility rate of the consumptive raw material. The utility rate can be dramatically improved from the 5% when using the conventional spin coating process to 95% with the present process.
3. The direct printing process is suitable for different types of the target substrates to be printed even when the target substrate may have a curved surface or be consisted of flexible material.

Even though the directing process possesses the foregoing features, some problems still need to be overcome, such as the width of the printed wires. For the present printing industry, the minimum drop size of the ejected substance is 20 pl. (pico-liter), and the width of the wire created by printing is approximate 30 um. Such a technique level is only suitable to create circuits on the printed circuit board (PCB). However, for example, it is not possible to use the direct printing process to fabricate the driving circuits of the TFT transistors (refer to FIG. 7). For the circuits that require a 3 um wire width, the drop size should be in the feno-liter (10⁻¹⁵) grade. To obtain the nano-grade drop size, the opening diameter of the nozzle should be accordingly minimized. However, to develop a novel nozzle with smaller diameter would possibly confront the difficulties of high manufacturing cost, low yield, or shortening the use life of the nozzle etc.

Many companies and institutions have invested many resources to develop new techniques concerning the direct printing. For example, Xenniz together with Carclo companies developed a technique that is able to print conductive wires of 50 um on the plastic or paper substance through the usage of the piezoelectricity-based printing means. R. H. Friend et al. published a printing technique that provided to construct “all polymer” transistors in the year 2000, however the 5 um wires in the gate channel region are still implemented by the conventional photolithography process. Moreover, Tanja et al. of Princeton University also proposed a new technique on the “Applied Physic Letters”. The technique according to the convective flow splitting phenomenon of the non-volatilizable solution forms initial wires of 500 um by dispensing the solution onto the substrate. After the solvent is finally evaporated, the initial wires of 500 um shrink to 100 um wires. Further, if by printing the solution to form the initial wires of 80 um, the final acquired wires would reach to 10 um width (see Tanja Cuk, “Using convectiveflow splitting for the directing printing of copper lines” Appl. Phys. Vol 77, No. 13, P2063). With reference to FIG. 8A, copper solution (700) is printed on a substrate (70) to form a wire of 80 um. Through a drying process, copper solute (72) contained in the solution (700) thus remains on the substrate (70) as shown in FIG. 8B. During the drying process, the coffee ring phenomenon would occur thus to cause different thicknesses on the remaining copper solute (72). The thickness of the middle region (72B) of the copper solute (72) is thinner than opposite edges (72A) of the copper solute (72). The width of the wire at each edge formed by copper solute (72A) is approximately 10 um.

Even though the foregoing printing process is capable of creating the narrow wires at the opposite edges, it is noted that the middle region (72B) still remains on the substrate (70) and connects to both edges (72A). Therefore, the entire remaining copper solute (72A)(72B) is deemed as one independent wire and unsuitable for practical application.

Moreover, another wire formation method is disclosed in the U.S. Patent application, publication number 2003/0151650. In which, as shown in FIGS. 1A to 1F of the publication application, a dispersion formed by dispersing a dispersoid in a dispersion medium is ejected onto a substrate.

Then, after the dispersion is spread over the substrate to form a desired pattern, the substrate on which the dispersion has landed is heated to only vaporize the dispersion medium and only the dispersoid is left on the substrate.

Then, a dispersion medium is ejected onto the dispersoid remaining on the substrate. As a result, a part of the dispersoid is taken up into the dispersion medium. When the substrate upon which the dispersion medium has landed on the dispersoid is heated again, the dispersoid dispersed within the dispersion medium again convects, and the dispersoid is driven to both sides.

The dispersoid then can be completely separated by repeated additional injections and heat drying of the dispersion medium. Thereafter, independent lines are formed.

The wire forming process as proposed in the foregoing publication application is quite complex and inefficient. Obviously, such a wire-forming method is not suitable for mass production of wires.

### SUMMARY OF THE INVENTION

An objective of the present invention is to provide a method for forming wires of sub-micron-order scale, wherein the line-width of the created independent wire is effectively narrowed.

To accomplish the objective, the method comprising the acts of:
applying solution on a substrate, wherein solute contained in said solution is able to be etched;
evaporating solvent of the solution applied on the substrate, whereby the solute remains on the substrate and integrally forms a first region and a second region, wherein the solute that forms the first region is thicker than the solute that forms the second region; and
comprehensively etching the solute remaining on the substrate, whereby the second region is removed and the first region is retained on the substrate as desired wires.

Another objective of the present invention is to provide a method for creating a photo-mask on which the wires of the nano-order scale are formed. To accomplish this objective, the method comprises the acts of:
applying solution on a mask target, wherein solute contained in said solution is able to be etched;
evaporating solvent of the solution applied on the mask target, whereby the solute thus remains on the mask target and integrally forms a first region and a second region, wherein the solute that forms the first region is thicker than the solute that forms the second region; and
comprehensively etching the solute remaining on the mask target, whereby the second region is removed and the first region is retained on the mask target as desired wires;
whereby the mask target becomes a photo-mask on which the desired wires are formed.

Other objects, advantages and novel features of the invention will become more apparent from the following detailed description when taken in conjunction with the accompanying drawings.

### BRIEF DESCRIPTION OF THE DRAWINGS

FIGS. 1A to 1D show the wires creation processes according to the present invention;

FIGS. 2A and 2B are the computer generated graphs showing the created ‘coffee ring’ according to the first experiment of the present invention, wherein the ‘coffee ring’ is not etched yet;

FIGS. 3A and 3B are the computer generated graphs showing the created ‘coffee ring’ according to the first experiment of the present invention, wherein the ‘coffee ring’ is etched;

FIGS. 4A and 4B are the computer generated graphs showing the created ‘coffee ring’ according to the second experiment of the present invention, wherein the ‘coffee ring’ is not etched yet;

FIGS. 5A and 5B are the computer generated graphs showing the created ‘coffee ring’ according to the second experiment of the present invention, wherein the ‘coffee ring’ is etched;

FIGS. 6A and 6B are the computer generated graphs showing the created ‘coffee ring’ according to the third experiment of the present invention, wherein the ‘coffee ring’ is etched;

FIG. 7 shows a table in which the relationship among drop size, drop diameter and width of created wires are listed; and

FIGS. 8A to 8B show the creation of wires according to the conventional printing process.

### DETAILED DESCRIPTION OF THE PREFERRED EMBODIMENT

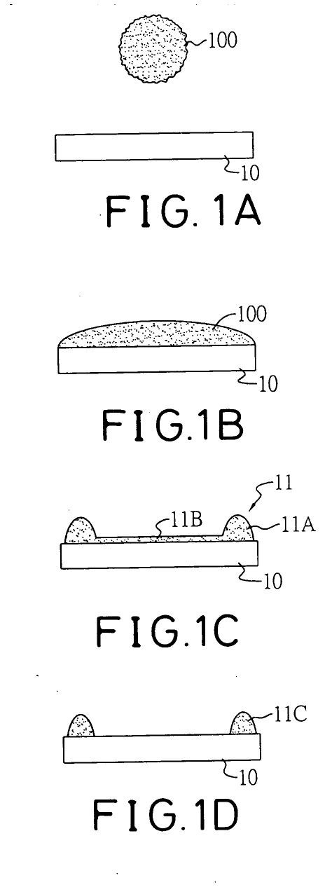

With reference to FIG. 1A, a solution (100) that contains a solute able to be etched is directly dispensed on a substrate (10). The solute in the solution (100) may be a metallic substance (such as copper), an organic substance (such as epoxy and polymethyl methacrylate (PMMA)), nano-conductors, semiconductors etc.

With reference to FIGS. 1B to 1C, after the solvent of the solution (100) has evaporated, the solute remaining on the substrate (10) forms a coffee ring configuration (11) because of the ‘coffee ring effect’. The coffee ring configuration (11) includes a first region (11A) and a second region (11B) with a different thickness. The first region (11A), i.e. the edge of the coffee ring configuration (11), is thicker than the second region (11B), i.e. the center portion.

With reference to FIG. 1D, an etching process is comprehensively applied on the substrate (10) to etch the coffee ring configuration (11). Because of the different thickness, the second region (11B) is completely removed from the substrate (10) and only the first region (11) remains to form a ring shaped wire. It is noted that wire width of the first region (11A) is further reduced because of the etching process.

The foregoing processes are for creating a ring shaped wire by dispensing solution drops. However, other desired patterns such as straight or curved lines are able to be created according to the foregoing processes by directly printing solution on the substrate.

In order to prove that the width of the created wire is effectively narrowed in accordance with the present invention, several experiments are proposed hereinafter.

Experiment 1: The solute is PMMA and the solvent is anisole, wherein the concentration of the mixed solution is 5%. The solution is printed on a glass substrate through a nozzle. After the anisole solvent has evaporated, a coffee ring configuration is formed on the glass substrate.

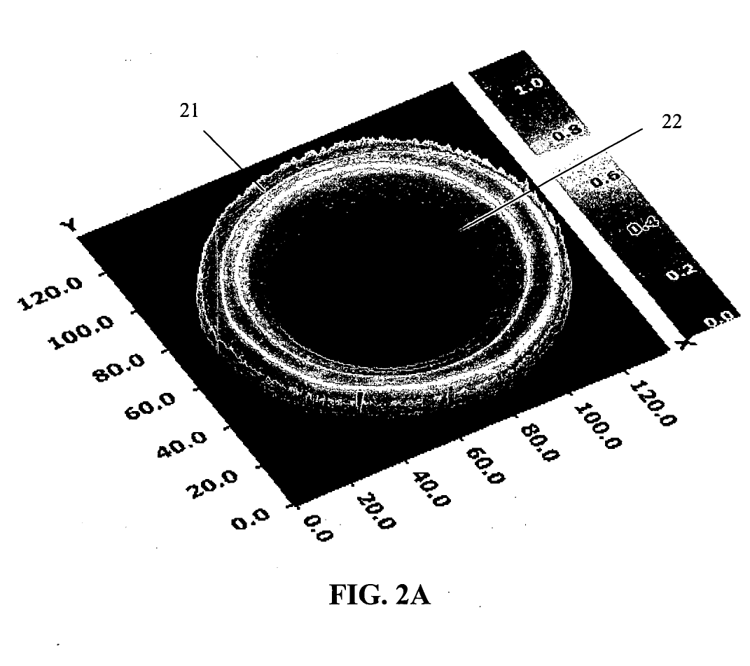

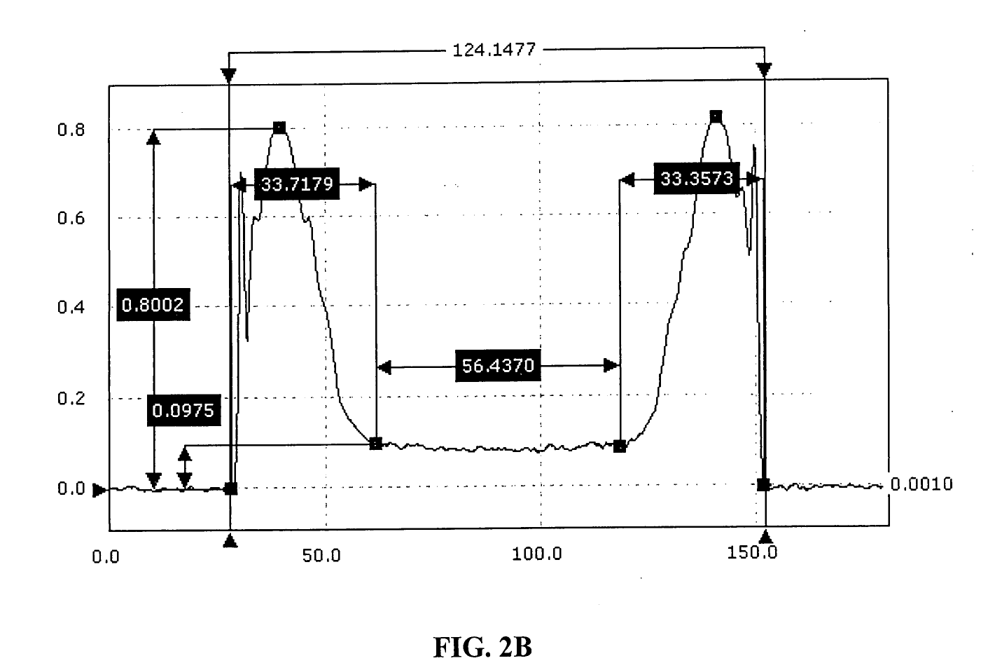

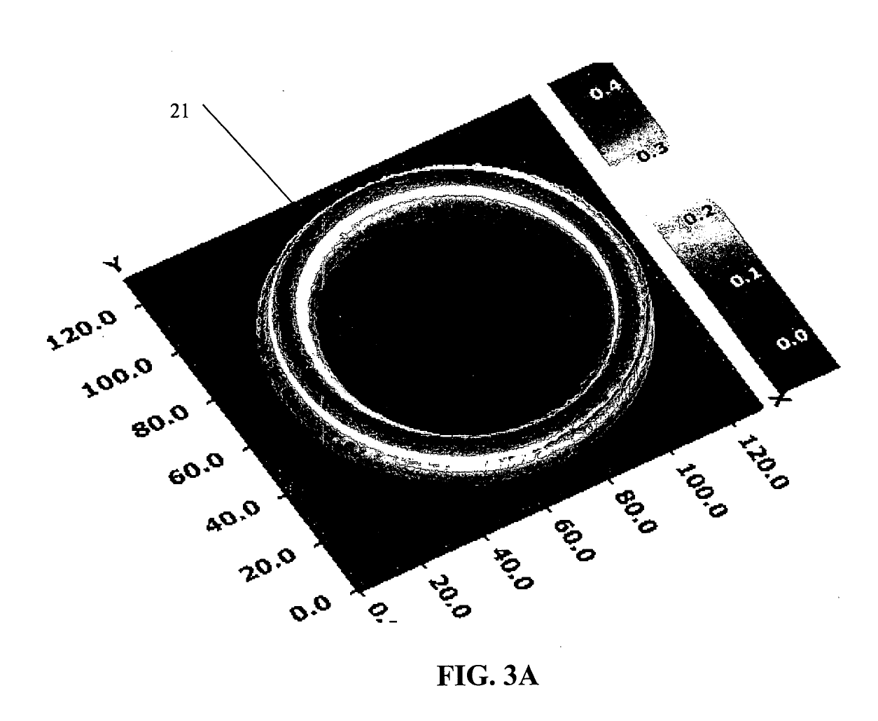

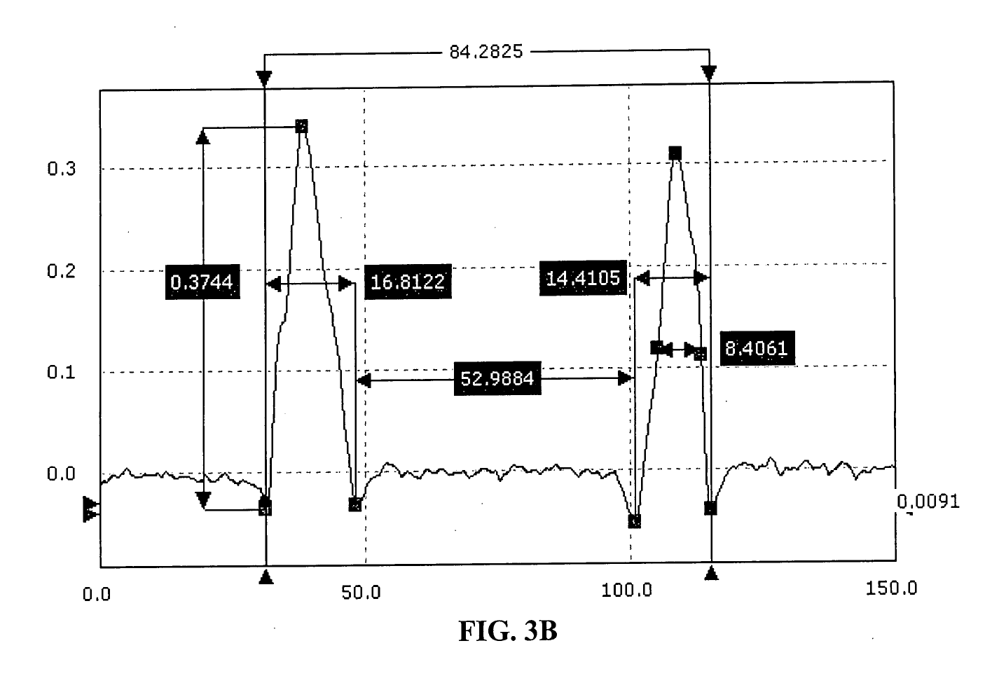

With reference to FIG. 2A, the coffee ring configuration is measured by an apparatus, wherein the periphery first region (21) is thicker than the central second region (22). The thickness distribution of the coffee ring is illustrated in FIG. 2B. The thickness of the first region (21) is approximately 0.8um and its width is approximate 33 um. The thickness of the second region (22) is only approximately 0.1 um and its width is approximate 56 um. With reference to FIGS. 3A and 3B, when the etching process is comprehensively applied on the coffee ring configuration, the second region (22) is removed and only a ring shaped first region (21) remains on the glass substrate. The thickness of the first region (21) becomes approximately 0.37 um and its width is approximate 16.8 um, wherein the width measured at the half height of the remaining first region (21) is only approximately 8 um.

Experiment 2: The solute is PMMA and the solvent is anisole, wherein the concentration of the mixed solution is 7%. The solution is also printed on a glass substrate to form a coffee ring configuration with two regions (31)(32) integrally formed together.

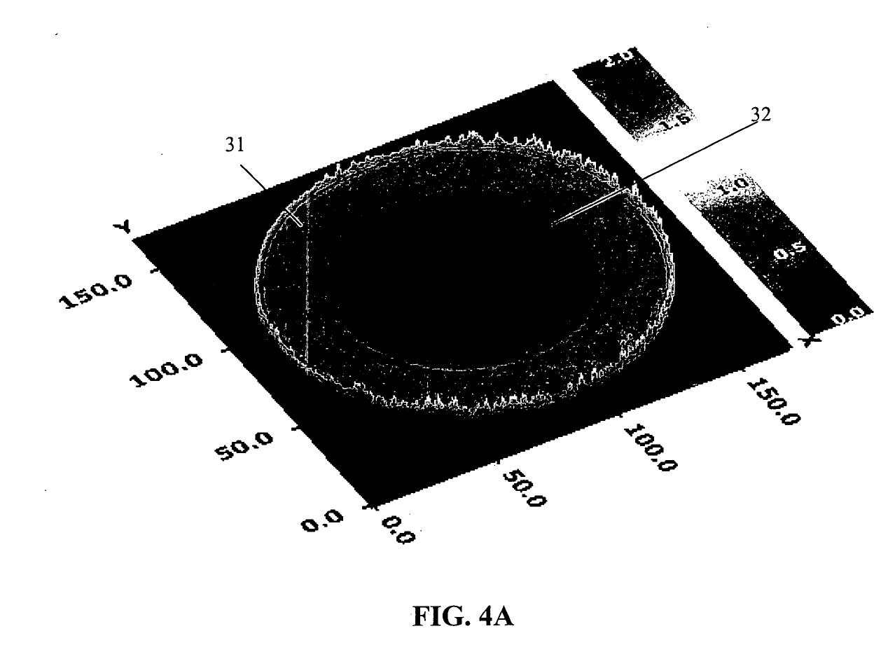

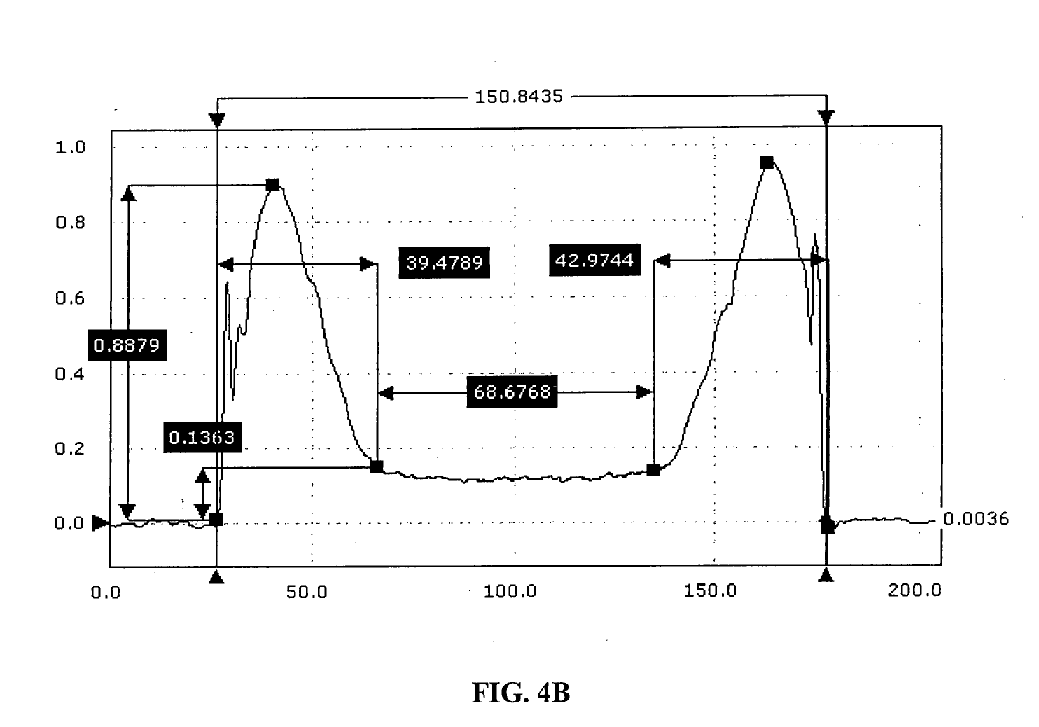

With reference to FIGS. 4A and 4B, the thickness of the first region (31) is approximately 0.89 um and its width is approximate 39 um before the etching process. The thickness of the second region (32) is only approximately 0.14 um and its width is approximately 64 um.

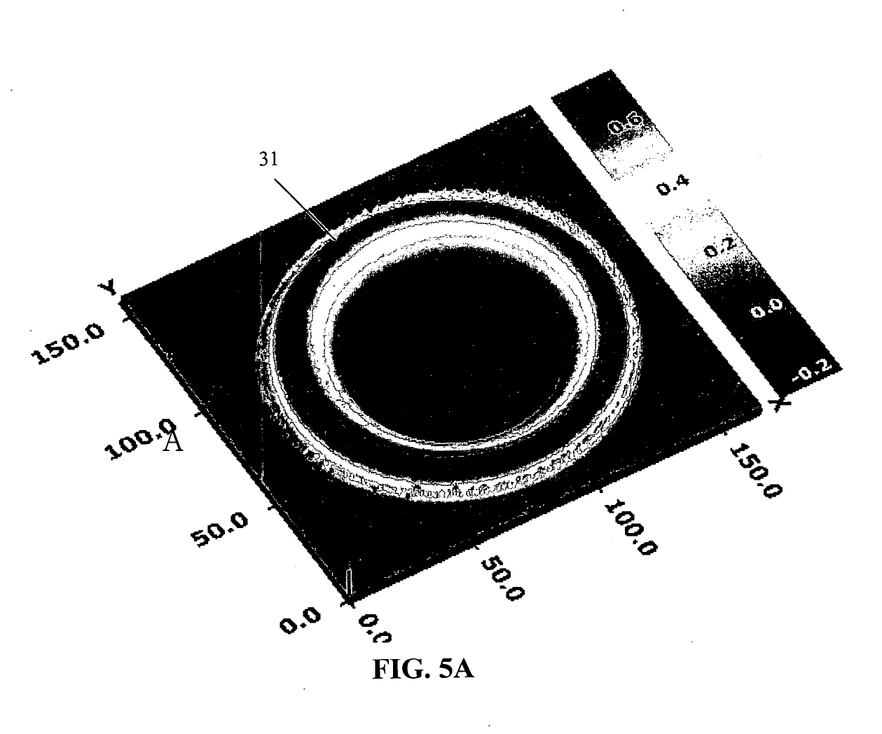

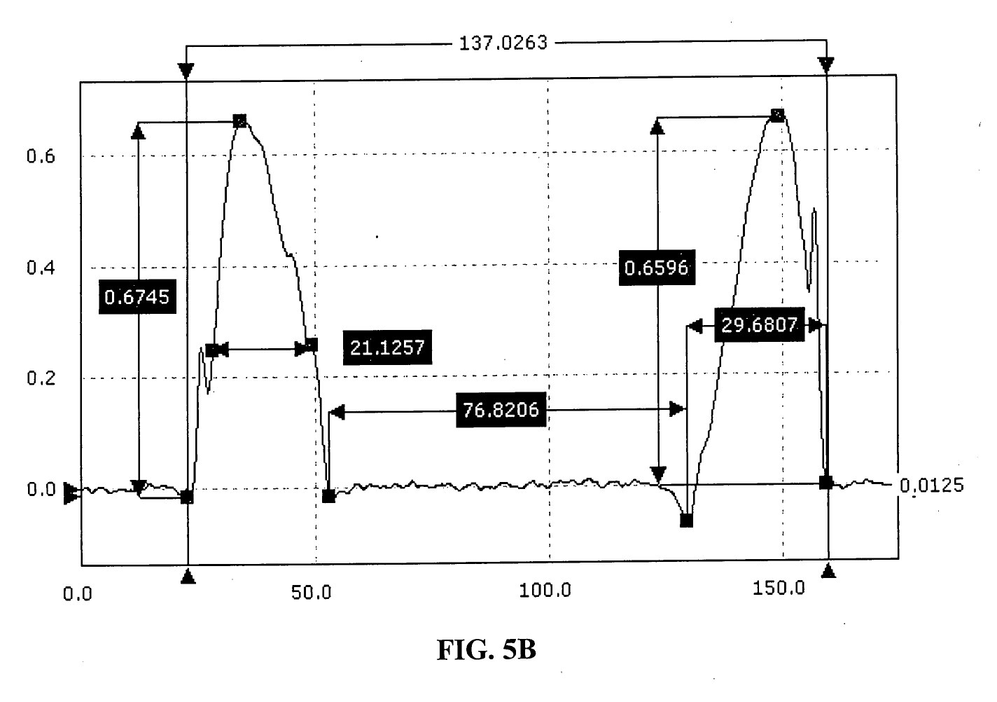

With reference to FIGS. 5A and 5B, after the etching process, the second region (32) is removed and only a ring shaped first region (31) remains on the glass substrate. The thickness of the first region (31) becomes approximately 0.67 um and its width is approximately 29.68 um, wherein the width measured at the half height of the remaining first region (31) is only approximately 21.1 um.

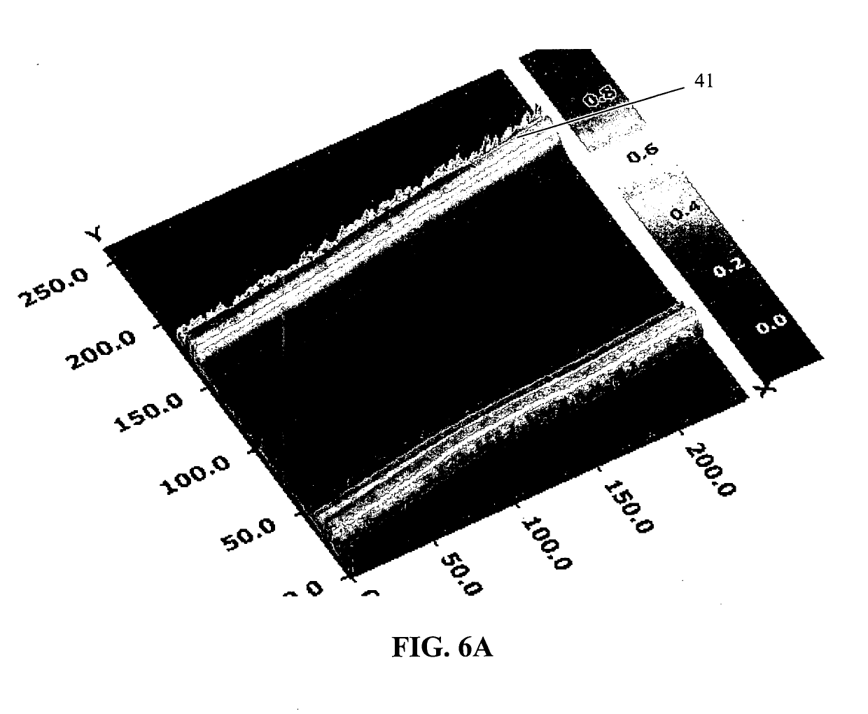

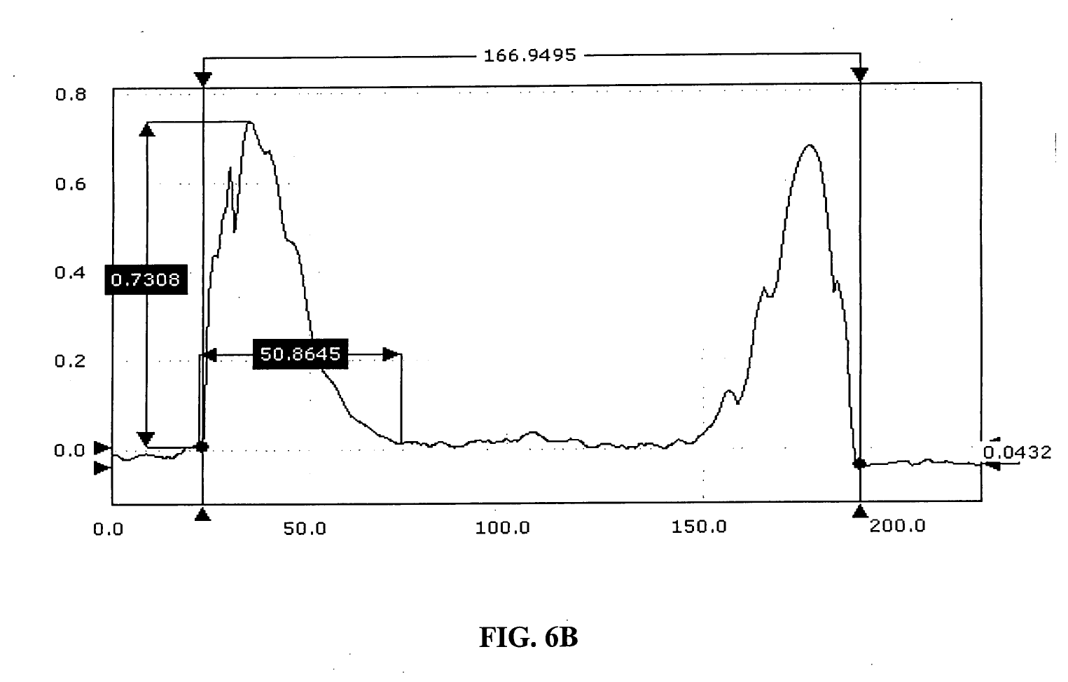

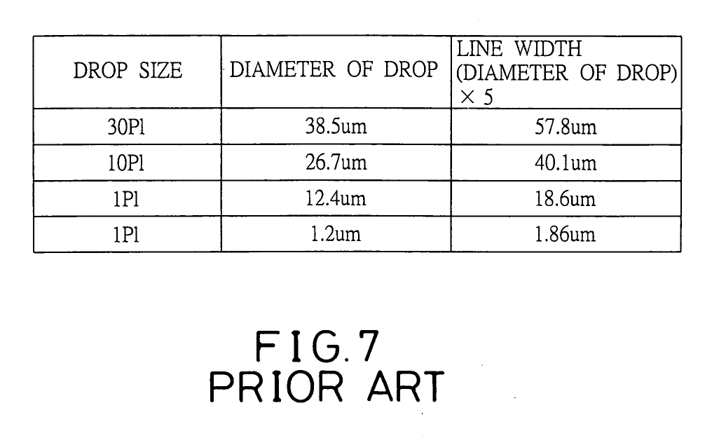

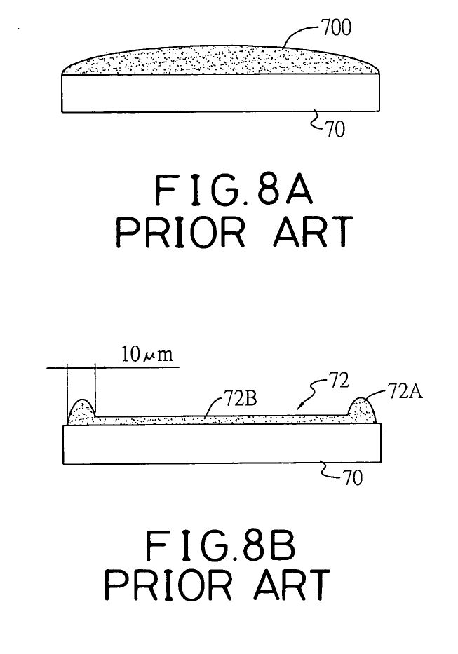

Experiment 3: The solute is PMMA and the solvent is anisole, wherein the concentration of the mixed solution is 5%. The solution is printed on a glass substrate to form the straight wire with two regions integrally formed together. The first region having the greater thickness includes the opposite edges of the straight wire, and the second region is the center portion of the wire. With reference to FIGS. 6A and 6B, after the etching process, the second region is removed and only a pair of straight lines (41) remains on the glass substrate. The thickness of the first region (41) becomes approximately 0.73 um and its width is approximately 50 um.

In FIG. 6A, the two created straight lines (41) are independent and parallel to each other. Such a pattern is quite suitable for an application in which multiple circuit wires are designed to be parallel to each other. In a condition that only one straight line is necessary, the other one is accordingly ignored.

Based on the foregoing description, by providing the solution containing the solute able to be etched on the substrate, the solute remaining on the substrate after the solvent is evaporated to form two regions with different thicknesses. Once an etching process is applied on the substrate, the region formed by the thinner solute-is completely removed and the other thicker region is retained as the desired independent wire.

Moreover, another purpose of the present invention is to form the wire patterns of a photo-mask adopted in general semiconductor processes, whereby through the pattern transferring process, a target objective can indirectly form nano-grade wires.

It is to be understood, however, that even though numerous characteristics and advantages of the present invention have been set forth in the foregoing description, the disclosure is illustrative only, and changes may be made in detail, within the principles of the invention to the full extent indicated by the broad general meaning of the terms in which the appended claims are expressed.

1. A method for forming wires or patterns, the method comprising the acts of:
applying a solution on a substrate, wherein a solute contained in said solution is able to be etched;
evaporating a solvent of the solution applied on the substrate, whereby the solute remains on the substrate and integrally forms a first region and a second region, wherein the solute that forms the first region is thicker than the solute that forms the second region; and
comprehensively etching the solute remaining on the substrate, whereby the second region is removed and the first region is retained on the substrate as desired wires.

2. The method as claimed in claim 1, wherein a width of the first region is smaller than a half width of the solution applied on the substrate.

3. The method as claimed in claim 1, wherein the solution is applied on the substrate by printing.

4. The method as claimed in claim 1, wherein the solution is applied on the substrate by dispensing.

5. The method as claimed in claim 1, the desired wire formed by the first region is ring shaped, linearly shaped or curved line shaped.

6. The method as claimed in claim 2, the desired wire formed by the first region is ring shaped, linearly shaped or curved line shaped.

7. The method as claimed in claim 3, the desired wires formed by the first region is ring shaped, linearly shaped or curved line shaped.

8. The method as claimed in claim 4, the desired wires formed by the first region is ring shaped, liearly shaped or curved line shaped.

9. The method as claimed in claim 1, wherein the solute is a metallic substance, an organic substance or a semiconductor substance.

10. The method as claimed in claim 2, wherein the solute is a metallic substance, an organic substance or a semiconductor substance.

11. The method as claimed in claim 3, wherein the solute is a metallic substance, an organic substance or a semiconductor substance.

12. The method as claimed in claim 4, wherein the solute is a metallic substance, an organic substance or a semiconductor substance.

13. The method as claimed in claim 1, wherein the substrate is a plastic substrate or a glass substrate.

14. The method as claimed in claim 2, wherein the substrate is a plastic substrate or a glass substrate.

15. The method as claimed in claim 3, wherein the substrate is a plastic substrate or a glass substrate.

16. The method as claimed in claim 4, wherein the substrate is a plastic substrate or a glass substrate.

17. A method for creating a photo-mask with wiresor patterns, the method comprising the acts of:
applying a solution on a mask target, wherein a solute contained in said solution is able to be etched;
evaporating a solvent of the solution applied on a mask target, whereby the solute thus remains on the mask target and integrally forms a first region and a second region, wherein the solute that forms the first region is thicker than the solute that forms the second region; and
comprehensively etching the solute remaining on the mask target, whereby the second region is removed and the first region is retained on the mask target as desired wires;
whereby the mask target becomes a photo-mask on which the desired wires are formed.

18. The method as claimed in claim 17, wherein a width of the first region is smaller than a half width of the solution applied on the mask target.

19. The method as claimed in claim 17, wherein the solution is applied on the mask target by printing.

20. The method as claimed in claim 17, wherein the solution is applied on the mask target by dispensing.

21. The method as claimed in claim 17, the desired wires formed by the first region are ring shaped, linearly shaped or curved line shaped.

22. The method as claimed in claim 18, the desired wires formed by the first region are ring shaped, linearly shaped or curved line shaped.

23. The method as claimed in claim 19, the desired wires formed by the first region are ring shaped, linearly shaped or curved line shaped.

24. The method as claimed in claim 20, the desired wires formed by the first region are ring shaped, linearly shaped or curved line shaped.

25. The method as claimed in claim 17, wherein the solute is a metallic substance, an organic substance or a semiconductor substance.

26. The method as claimed in claim 18, wherein the solute is a metallic substance, an organic substance or a semiconductor substance.

27. The method as claimed in claim 19, wherein the solute is a metallic substance, an organic substance or a semiconductor substance.

28. The method as claimed in claim 20, wherein the solute is a metallic substance, an organic substance or a semiconductor substance.

29. The method as claimed in claim 17, wherein the mask target is composed of glass or plastic material.

30. The method as claimed in claim 18, wherein the mask target is composed of glass or plastic material.

31. The method as claimed in claim 19, wherein the mask target is composed of glass or plastic material.

32. The method as claimed in claim 20, wherein the mask target is composed of glass or plastic material.
